(19) United States
(12) Patent Application Publication
(10) Pub. No.: US 2026/0351694 A1
(43) Pub. Date: Nov. 5, 2026

(54) CELLULAR BATTERY WITH ONE OR MORE NON-DISRUPTIVE SWITCHING DEVICES, FOR A BATTERY ASSEMBLY OF A SYSTEM

(71) Applicant: STELLANTIS AUTO SAS, Poissy (FR)

(72) Inventors: Pierre-Mikael VIOLLIN, VERSAILLES (FR); Eric MIZWICKI, MENUCOURT (FR); Serge DA CRUZ PEREIRA, SAINT OUEN L'AUMONE (FR); Didier SORRENTINO, BESSANCOURT (FR)

(21) Appl. No.: 19/487,471

(22) PCT Filed: May 14, 2024
(86) PCT No.: PCT/FR2024/050616

§ 371 Date: Nov. 24, 2025

(30) Foreign Application Priority Data
Jun. 1, 2023 (FR) FR2305481

(51) Int. Cl. H01M 10/42; B60L 50/64; B60L 58/18; G01R 31/396; H01M 10/48; H01M 16/00

(52) U.S. Cl. CPC H01M 10/425; G01R 31/396; H01M 10/48; H01M 16/00; B60L 50/64; B60L 58/18; H01M 2010/4271

(57) ABSTRACT

A battery (BC) comprises M modules (MC), each comprising at least one electrical energy storage cell (CE), which modules are mounted in series with a switching device (DC) having open and closed states, and are coupled to analysis devices (DA) determining present values of quantities representative of the cells (CE) and communicating with one another via a communication line (LC) comprising isolation capacitors, some of which are coupled to terminals of the switching device (DC). This battery (BC) further comprises a resistive element (ER) mounted in parallel with the switching device (DC) in order to minimize the voltage, across the isolation capacitors coupled to the terminals of the switching device (DC), to prevent communication over the communication line (LC) from being interrupted when the switching device (DC) is in its open state.

### CROSS-REFERENCE TO RELATED APPLICATIONS

This application is the US National Stage under 35 USC § 371 of International Application No. PCT/FR2024/050616, filed May 14, 2024, which claims priority from French application No. 2305481 filed on Jan. 6, 2023 the content (text, drawings and claims) of both said applications being incorporated by reference herein.

### BACKGROUND

Disclosed herein are cellular batteries comprising at least one anti-thermal runaway switching device and intended to form part of a battery assembly of a system.

In many systems, such as for example vehicles (optionally of the automotive type), cellular batteries are used as part of (cellular) modules mounted in series. The term “cellular battery” herein refers to a battery comprising M modules, each comprising at least one electrical energy storage cell, and mounted in series with at least one switching device (with open and closed states), with M≥2.

For example, in a vehicle, the cellular battery is generally coupled to at least one electric motor of a powertrain (or PT) in order to supply it with current to produce drive torque, and optionally to be supplied with recharging current by this electric motor. Note that in such an example, the cellular battery constitutes a main (or traction) battery. It should also be noted that in such a cellular battery, the electrical energy storage cells may optionally be electrochemical (for example of the lithium-ion (or Li-ion) or Ni—Mh or Ni—Cd type).

Sometimes, a cellular battery forms part of a battery assembly (or “pack”) which also comprises a battery housing comprising analysis devices for determining present values of quantities representative of the cells and communicating with one another via a communication line comprising isolation capacitors, and a battery computer coupled to said communication line to receive the determined present values and responsible for controlling the operation of said cellular battery based on said received values.

As the (each) switching device of a cellular battery is mounted in series between two cellular modules, it can at least delay the thermal runaway of its cellular battery when it is placed in its open state by the battery computer. This is particularly important for the safety of the vehicle, its passengers and the surrounding environment.

However, because it is mounted in series between two cellular modules, a switching device is coupled to some of the isolation capacitors on the communication line that supplies the battery computer with the present values determined. Thereby, when a switching device is placed in its open state, this causes the isolation capacitors coupled across its terminals to be charged, which causes them to lose a significant part of their capacitance effect. As a result, communication between the two analysis devices that are coupled via these charged isolation capacitors is impacted and the “receiving” analysis device determines that there is an interruption in communication over the communication line.

It will be understood that such an interruption prevents the battery computer, when starting up its system (for example a vehicle), from initializing communication with the analysis devices, in order to receive the present values of quantities representative of the cells. In the absence of this reception, the battery computer is unable to determine whether it is possible to place each analysis device in its closed state, and therefore it generates an alert message signaling a failure, and prevents the cellular battery from being used (which prevents the vehicle from moving when its powertrain is all-electric).

The aim is therefore especially to improve the situation.

### SUMMARY

For this purpose, a battery is notably proposed, intended to form part of a system, and comprising M modules, on the one hand, each comprising at least one electrical energy storage cell, on the other hand, mounted in series with at least one switching device having open and closed states, with M≥2, and, on the third hand, adapted to being coupled to analysis devices adapted to determine present values of quantities representative of these cells and communicating with one another via a communication line comprising isolation capacitors, some of which are adapted to be coupled to terminals of the (of a) switching device.

This battery is characterized by the fact that it also comprises at least one resistive element mounted in parallel with the (one) switching device in order to minimize a voltage, across the isolation capacitors which are coupled to the terminals of this switching device, to prevent communication over the communication line from being interrupted when this switching device is in its open state.

The disclosed switching device is “non-disruptive” for the communication line when it is placed in its open state, since it can no longer induce an interruption in communication over this communication line.

The battery may comprise other features which can be taken separately or in combination, and especially:
the (each) resistive element may have a first resistance which is a function of a second equivalent resistance of the communication line with the analysis devices;
in a first option, the first resistance may be between 90% of the second equivalent resistance and 110% of the second equivalent resistance;
in a particular embodiment, the first resistance may be between 600 kΩ and 1 MΩ when the second equivalent resistance is between 600 kΩ and 1 MΩ;
the (each) resistive element may comprise at least one resistor;
the (each) switching device may be a relay;
the cells can be of the electrochemical type.

Also described is a battery assembly comprising:
a battery housing comprising analysis devices adapted to determine present values of quantities representative of the cells and communicating with one another via a communication line comprising isolation capacitors,
a battery calculator coupled to this communication line to receive the present values determined, and
a battery of the type shown above and having its modules coupled to the analysis devices and each switching device coupled to some of the isolation capacitors.

Also described is a system comprising at least one battery assembly of the type shown above.

For example, this system can be a vehicle. In this case, the vehicle may comprise a powertrain (or PT) comprising at least one electric motor coupled to the battery assembly.

### BRIEF DESCRIPTION OF THE FIGURES

Other features and advantages will become apparent from examining the detailed description hereinafter, and the appended drawings, in which:

FIG. 1 schematically and functionally shows an example embodiment of a vehicle comprising an example embodiment of a battery assembly and a powertrain drive chain with an electric motor coupled to this battery assembly, and

FIG. 2 schematically and functionally shows a wiring diagram equivalent to the battery assembly shown in FIG. 1.

### DETAILED DESCRIPTION

In particular, a battery BC is provided which is intended to form part of a battery assembly EB, itself intended to equip a system S and also comprising a battery housing BB, and not inducing interruption of the communication line LC of the battery housing BB when the (one) switching device DC which it comprises is in its open state.

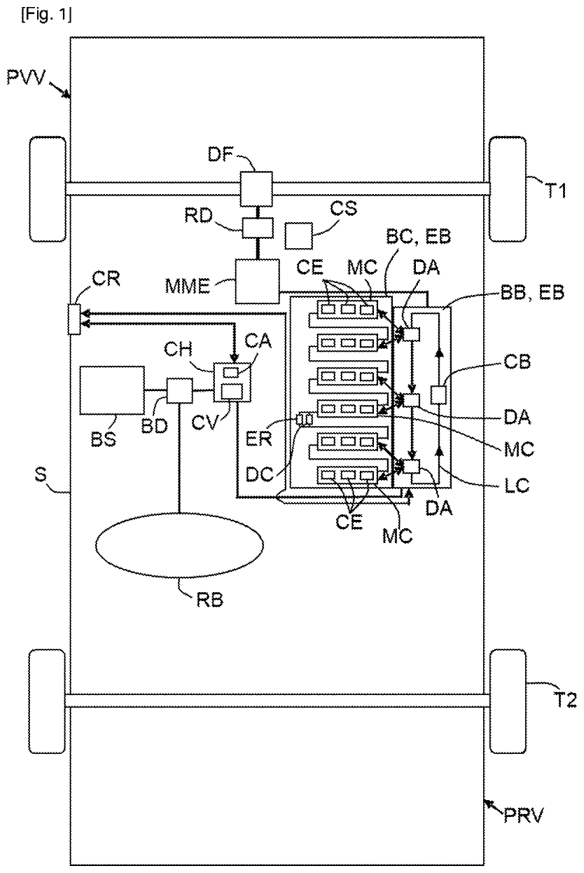

In the following, by way of a non-limiting example, the system S is assumed to be a motor vehicle, such as for example a car, as shown in FIG. 1. However, the described systems are not limited to this type of system. Indeed, it relates to any type of system comprising at least one battery assembly with a cellular battery. Thus, it applies to vehicles (land, sea (or river) and air), buildings and installations (optionally industrial).

Furthermore, by way of a non-limiting example, it is considered that the vehicle S comprises a drive train with a powertrain (or PT) of the all-electric type (and therefore the drive is provided exclusively by at least one electric motor MME). However, the powertrain could be hybrid (combustion and electric).

FIG. 1 schematically shows a system S (herein a vehicle) comprising a drive train with an electric powertrain (and therefore an electric motor MME), a supervision computer CS, an on-board network RB, a service battery BS, a battery assembly EB comprising a cellular battery BC and a battery housing BB, and a power supply system.

The power supply system comprises a main electrical circuit connected to a power connector CR and a charger CH comprising a charger computer CA and herein a converter CV, as well as the electric motor MME.

The on-board network RB is a power supply network to which electrical (or electronic) equipment (or components) that consume electrical energy are connected.

The service battery BS is responsible for providing electrical energy to the on-board network RB, in addition to that provided by the converter CV fed by the cellular battery BC via the main electrical circuit, and sometimes in place of this converter CV. For example, the service battery BS may be a very low-voltage battery (typically 12 V, 24 V or 48 V). It can be recharged at least by the converter CV. As a non-limiting example, the service battery BS is of the 12 V lithium-ion type.

The main (or “high voltage”) electrical circuit is more specifically connected, on the one hand, to the cellular battery BC via the battery housing BB, and, on the other hand, to electronic equipment, such as for example the converter CV and the electric motor MME. It also enables the cellular battery BC to be recharged by an external power source and temporarily coupled to the power connector CR of the vehicle S. In the non-limiting example shown in FIG. 1, the main electrical circuit enables the cellular battery BC to be recharged not only in direct current (or mode 4), but also in alternating current (or mode 2 or 3), under the control of the charger computer CA (of the charger CH) and the battery computer CB (of the battery housing BB). However, in alternative embodiments not shown, the main electrical circuit may allow only direct current recharging (or mode 4) or only alternating current recharging (or mode 2 or 3).

The drive chain has a powertrain which is, herein, purely electrical and therefore comprises, notably, an electric motor MME, a motor shaft AM, and a drive shaft AT. The term “electric motor” herein refers to an electrical machine designed to provide torque to move the vehicle S when it is supplied with electrical energy, and optionally to recover torque from the drive train.

The operation of the drive train (and therefore of the PT) is supervised by a supervision computer CS.

The electric motor MME (herein an electric motor) is herein coupled to the cellular battery BC via the main electrical circuit and the battery housing BB, in order to be supplied with electrical energy, as well as optionally to supply this cellular battery BC with electrical energy, for example during a regenerative braking phase.

Furthermore, this electric motor MME is coupled to the motor shaft AM, to provide it with rotational drive torque. This motor shaft AM is herein coupled to a reduction gearbox RD which is also coupled to the drive shaft AT, itself coupled to a first set T1 (herein of wheels), preferably via a differential DV.

This first set T1 is herein located in the front part PW of the vehicle S. But in one variant, this first set T1 could be the one referred to herein as T2 and which is located in the rear part PRV of the vehicle S.

The converter CV can also be responsible for converting part of the electric current stored in the cellular battery BC to supply converted electric current to the on-board network RB and the service battery BS (for recharging) during the driving phases of the vehicle S.

Note that, in the non-limiting example shown in FIG. 1 and as indicated hereinbefore, the converter CV can form part of the charger CH which also comprises the charger computer CA responsible, at least, for controlling the recharges of the cellular battery BC.

As the cellular battery BC supplies herein the electric motor MME, it constitutes a main (or traction) battery. It (BC) comprises M modules MC each comprising at least one electrical energy storage cell CE, and mounted in series with at least one switching device DC having open and closed states, with M≥2.

The (each) switching device DC prevents current from flowing into its cellular battery BC when it is placed in its open state by the battery computer CB. In this case, it (DC) at least delays thermal runaway of its cellular battery BC.

Note that in the non-limiting example shown in FIG. 1, the cellular battery BC comprises only a switching device DC mounted in series between two cellular modules MC. But the cellular battery BC could comprise several (at least two) switching devices DC.

For example, the (each) switching device DC may be a relay (preferably static (and therefore fully electronic)). But this is not mandatory, as the important thing is that it comprises an open (or non-passing) state and a closed (or passing) state.

It should also be noted that in the non-limiting example shown in FIG. 1, the cellular battery BC comprises six (M=6) cellular modules MC. But the number of cellular modules MC can take any value greater than or equal to two.

It should also be noted that in the non-limiting example shown in FIG. 1, each cellular module MC comprises three (electrical energy storage) cells CE. But the number of cells CE in each cellular module MC can take any value greater than or equal to one.

For example, the cells CE can be of the electrochemical type (for example lithium-ion (or Li-ion) or Ni—Mh or Ni—Cd). Also, for example, the cellular battery BC can be of the low-voltage type (typically 450 V by way of illustration). But it could be medium-voltage or high-voltage.

Furthermore, the battery housing BB also comprises analysis devices DA which are suitable for determining present values of quantities representative of the cells CE and which communicate with one another via a communication line LC comprising isolation capacitors (not shown). This communication line LC is coupled to the battery computer CB so that it can receive these determined present values and control the operation of the cellular battery BC based on these determined and received present values.

For example, the quantities whose values are determined by a analysis device DA may be cell temperatures and voltages.

Note that in the non-limiting example shown in FIG. 1, each analysis device DA is associated with and coupled to two cellular modules MC. But the number of cellular modules MC to which an analysis device DA can be coupled can take any value greater than or equal to one.

Note also that some of the isolation capacitors are coupled across the (a) switching device DC. More specifically, this is the case for those associated with the cellular module MC coupled to one of the terminals of the (of a) switching device DC.

It should also be noted that in the non-limiting example shown in FIG. 1, the vehicle S further comprises a distribution box BD to which the service battery BS, the converter CV and the on-board network RB are coupled. This distribution box BD is responsible for distributing to the on-board network RB the electrical energy stored in the service battery BS or produced by the converter CV, in order to supply the electrical components (or equipment) coupled to the on-board network RB based on the supply requests received (notably from the supervision computer CS of the PT).

As shown in FIG. 1, the cellular battery BC also comprises at least one resistive element ER which is mounted in parallel with the (a) switching device DC in order to minimize the voltage across the isolation capacitors which are coupled across the terminals of this switching device DC. This minimization is intended to prevent communication over the communication line LC from being interrupted when the switching device DC is in its open state.

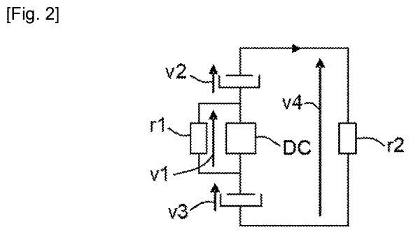

Indeed, it will be seen from the equivalent electrical diagram of the battery assembly EB shown in FIG. 2 that installing a resistive element ER in parallel with the terminals of a switching device DC means defining a voltage divider that minimizes the voltage across the isolation capacitors concerned, and therefore prevents the latter from charging when the switching device DC is placed in its open state. Thereby, the information bits, which are communicated via the communication line LC by propagation from one analysis device DA to the next analysis device DA, are at a sufficiently high level to remain interpretable, which means that there is no interruption in communication over the communication line LC when the switching device DC is placed in its open state. In other words, the switching device DC is now non-disruptive for the communication line LC when it is placed in its open state.

In the equivalent electrical diagram of the battery assembly EB shown in FIG. 2:
the first resistance r1 represents the resistance of the resistive element ER,
the second resistance r2 represents the equivalent resistance of the communication line LC with the analysis devices DA,
the reference v1 represents the first voltage at the terminals of the switching device DC and therefore of the resistive element ER,
the reference v2 represents the second voltage generated by the cellular modules MC which are located downstream of the switching device DC and therefore of the resistive element ER,
the reference v3 represents the third voltage generated by the cellular modules MC which are located upstream of the switching device DC and therefore of the resistive element ER, and
the reference v4 represents the fourth voltage at the terminals of the cellular battery BC, and which is equal to v2+v3 when the first voltage v1 is neglected.

With such an equivalent electrical diagram, the first voltage v1 is given by the equation v1=*v4, and the second voltage v2 is given by the equation v2=*v4.

It is important to note that the voltage divider thus constituted is dimensioned in such a way that it is always possible to carry out diagnostics on the switching device DC (it must be possible to determine, by comparing voltage measurements taken upstream and downstream of the switching device DC, whether the latter (DC) is in its open state or its closed state).

To this end, the (each) resistive element ER may have a first resistance r1 which is a function of the second equivalent resistance r2 of the communication line LC with the analysis devices DA. In this case, the first resistance r1 can, for example, be between 90% of the second equivalent resistance r2 and 110% of the second equivalent resistance r2.

For example, the first resistance r1 can be between 600 kΩ and 1 MΩ when the second equivalent resistance r2 is also between 600 kΩ and 1 MΩ. As an illustrative example, the first resistance r1 can be equal to 800 kΩ when the second equivalent resistance r2 is equal to 800 kΩ. These values for the first r1 and second r2 resistances are particularly well suited to the case where the fourth voltage v4 across the terminals of the cellular battery BC is about 400 V.

It can be shown that, in the presence of the values (r1, r2 and v4) mentioned in the previous paragraph and isolation capacitors having a capacitance of 6.8 nF, the parallel connection of a resistive element ER and of a switching device DC generates a 109 V reduction in the voltage across the isolation capacitors concerned. As a result, the loss of capacitance caused by this reduction is only 10%, which corresponds to a reduced capacitance equal to 6.12 nF (instead of 6.8 nF), i.e. almost three times the minimum required (2.2 nF) for the bits of information communicated by the communication line LC to be at a high enough level to remain interpretable.

Also, for example, the (each) resistive element ER may comprise at least one resistor. Thus, it may comprise one or more resistors (at least two) mounted in series and/or in parallel, or else it may be an “RP” type filter or an “RC” type device, for example.

1. A battery comprising M modules i) each comprising at least one electrical energy storage cell, ii) mounted in series with at least one switching device having open and closed states, with M≥2, and iii) adapted to be coupled to analysis devices adapted to determine present values of quantities representative of said cells and communicating with one another via a communication line comprising isolation capacitors, some of which are adapted to be coupled to terminals of said switching device, wherein the battery further comprises at least one resistive element mounted in parallel with said switching device in order to minimize a voltage, across said isolation capacitors coupled to said terminals of the switching device, to prevent communication over said communication line from being interrupted when said switching device is in its open state.

2. The battery according to claim 1, wherein said resistive element has a first resistance based on a second equivalent resistance of said communication line with said analysis devices.

3. The battery according to claim 2, wherein said first resistance is between 90% of said second equivalent resistance and 110% of said second equivalent resistance.

4. The battery according to claim 3, wherein said first resistance is between 600 kΩ and 1 MΩ when said second equivalent resistance is between 600 kΩ and 1 MΩ.

5. The battery according to claim 1, wherein said resistive element comprises at least one resistance.

6. The battery according to claim 1, wherein said switching device is a relay.

7. The battery according to claim 1, wherein said cells are of the electrochemical type.

8. A battery assembly comprising a battery housing comprising i) analysis devices adapted to determine present values of quantities representative of the cells and communicating with one another via a communication line comprising isolation capacitors, and ii) a battery computer coupled to said communication line for receiving said determined present values, wherein it further comprises a battery according to claim 1, having its modules coupled to said analysis devices and each switching device coupled to some of said isolation capacitors.

9. A system, comprising at least one battery assembly according to claim 8.

10. The system according to claim 9, wherein the system is a vehicle.
